(19) United States
(12) Patent Application Publication
(10) Pub. No.: US 2002/0145141 A1
(43) Pub. Date: Oct. 10, 2002

(54) Gate-overlapped lightly doped drain polysilicon thin film transistor

(76) Inventor: Chih-Chiang Chen, I-Lan Hsien (TW)

Correspondence Address: OPPENHEIMER WOLFF & DONNELLY, P. O. BOX 10356, PALO ALTO, CA, 94303, US

(21) Appl. No.: 09/892,232

(22) Filed: Jun. 26, 2001

(30) Foreign Application Priority Data
Apr. 10, 2001 (TW) 90108724

(51) Int. Cl. H01L 29/76

(52) U.S. Cl. 257/66; 257/408

(57) ABSTRACT

A gate-overlapped lightly doped drain (LDD) polysilicon thin film transistor (TFT) has a transparent insulating substrate, a polysilicon layer formed on the substrate, and a gate insulating layer formed on the polysilicon layer. The polysilicon layer has a channel region, an LDD structure surrounding the channel region, and a source/drain region surrounding the LDD structure. A first gate layer is patterned on the gate insulating layer and positioned over the channel region. A second gate layer is patterned on the first gate layer and extends to cover a predetermined area of the gate insulating layer that covers the LDD structure.

### BACKGROUND OF THE INVENTION

1. Field of the Invention

The present invention relates to a polysilicon thin film transistor (poly-Si TFT) and, more particularly, to a gate-overlapped lightly doped drain (LDD) poly-Si TFT.

2. Description of the Related Art

Thin film transistor technology (TFT), used in liquid crystal display (LCD), serving as a switch element, is categorized as amorphous TFT and polysilicon TFT. Polysilicon TFT provides higher carrier mobility, greater integration of driving circuits, and smaller leakage current, and is, therefore, more commonly used in high-operation circuits and large-size LCD applications.

A conventional gate-overlapped polysilicon TFT has superior ability to control the electric performance of the channel, but has a problem of leakage current occurred in the depletion region near the drain. To solve this problem, a lightly doped drain (LDD) structure is used in the polysilicon TFT to decrease the leakage current. However, the LDD structure increases the series resistance of the source and drain, thereby reducing on-current intensity and operating speed of the polysilicon TFT.

Recently, a gate-overlapped LDD polysilicon TFT has been proposed to decrease leakage current without sacrificing the On-current and thus achieve the advantages of conventional gate-overlapped polysilicon TFT and LDD polysilicon TFT. FIG. 1 is a cross-sectional diagram of a gate-overlapped LDD polysilicon TFT according to the prior art. The gate-overlapped LDD polysilicon TFT has a transparent insulating substrate 10, a polysilicon layer 12 formed on the substrate 10, a gate insulating layer 20 formed on a predetermined area of the polysilicon layer 12, a gate layer 22 formed on the gate insulating layer 20, and a dielectric layer 24 formed on the exposed area of the polysilicon layer 12 and the gate layer 22. The polysilicon layer 12 has an LDD structure 16 surrounding the gate layer 22, a source/drain region 14 surrounding the LDD structure 16, and a channel 18 below the gate layer 22. Also, a sub-gate layer 26 passes through the dielectric layer 24 to electrically connect to the gate layer 22, and extends to cover a part of the dielectric layer 24 over the LDD structure 16 and the source/drain region 14. In addition, a source/drain electrode 28 passes through the dielectric layer 24 to electrically connect to the source/drain region 14.

In the fabrication of the gate-overlapped LDD polysilicon TFT, an extra photo mask is required to pattern the source/drain region 14 and the LDD structure 16, and thus the self-aligned pattern cannot be accurately controlled during ion implantation. Furthermore, in pattering the sub-gate layer 26, the limitation of exposure technique cannot assure that the sub-gate layer 26 extends to overlap the LDD structure 16. Therefore, a problem of the alignment of the source/drain region 14, the LDD structure 16 and the sub-gate layer 26 needs to be solved.

### SUMMARY OF THE INVENTION

The present invention provides a gate-overlapped lightly doped drain (LDD) polysilicon thin film transistor (TFT) to decrease leakage current without sacrificing the On-current and accurately align the source/drain region, the LDD structure and the sub-gate layer.

The gate-overlapped lightly doped drain (LDD) polysilicon thin film transistor (TFT) has a transparent insulating substrate, a polysilicon layer formed on the substrate, and a gate insulating layer formed on the polysilicon layer. The polysilicon layer has a channel region, an LDD structure surrounding the channel region, and a source/drain region surrounding the LDD structure. A first gate layer is patterned on the gate insulating layer and positioned over the channel region. A second gate layer is patterned on the first gate layer and extends to cover a predetermined area of the gate insulating layer that covers the LDD structure.

The present invention also provides a method of forming the gate-overlapped LDD polysilicon TFT. A transparent insulating substrate has a polysilicon layer, a gate insulating layer formed on the polysilicon layer, and a first gate layer patterned on the gate insulating layer. A first ion implantation process is performed to form a lightly doped region on the polysilicon layer surrounding the first gate layer. Then, a second gate layer is formed on the first gate layer, wherein the second gate layer extends to cover a predetermined area of the gate insulating layer that is over part of the lightly doped region. Next, a second ion implantation process is performed to form a heavily doped region on the lightly doped region that surrounds the second gate layer.

Accordingly, it is a principal object of the invention to provide the gate-overlapped LDD polysilicon TFT to decrease leakage current without sacrificing the On-current.

It is another object of the invention to accurately align the source/drain region, the LDD structure and the second gate layer.

Yet another object of the invention is to provide the second gate layer to protect the first gate 42 to increase the reliability.

It is a further object of the invention to simplify the method of forming the gate-overlapped LDD polysilicon TFT.

These and other objects of the present invention will become readily apparent upon further review of the following specification and drawings.

### BRIEF DESCRIPTION OF THE DRAWINGS

FIG. 1 is a cross-sectional diagram of a gate-overlapped LDD polysilicon TFT according to the prior art.

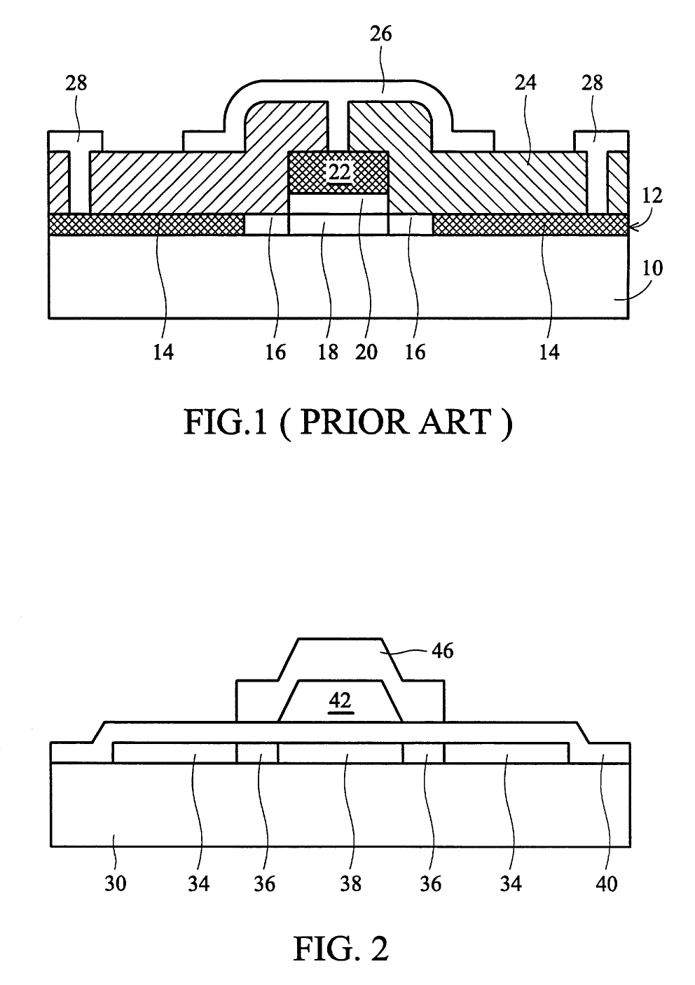

FIG. 2 is a cross-sectional diagram of a gate-overlapped LDD polysilicon TFT according to the present invention.

FIGS. 3A to 3D are cross-sectional diagrams showing a method of forming the gate-overlapped LDD polysilicon TFT shown in FIG. 2.

Similar reference characters denote corresponding features consistently throughout the attached drawings.

### DETAILED DESCRIPTION OF THE PREFERRED EMBODIMENTS

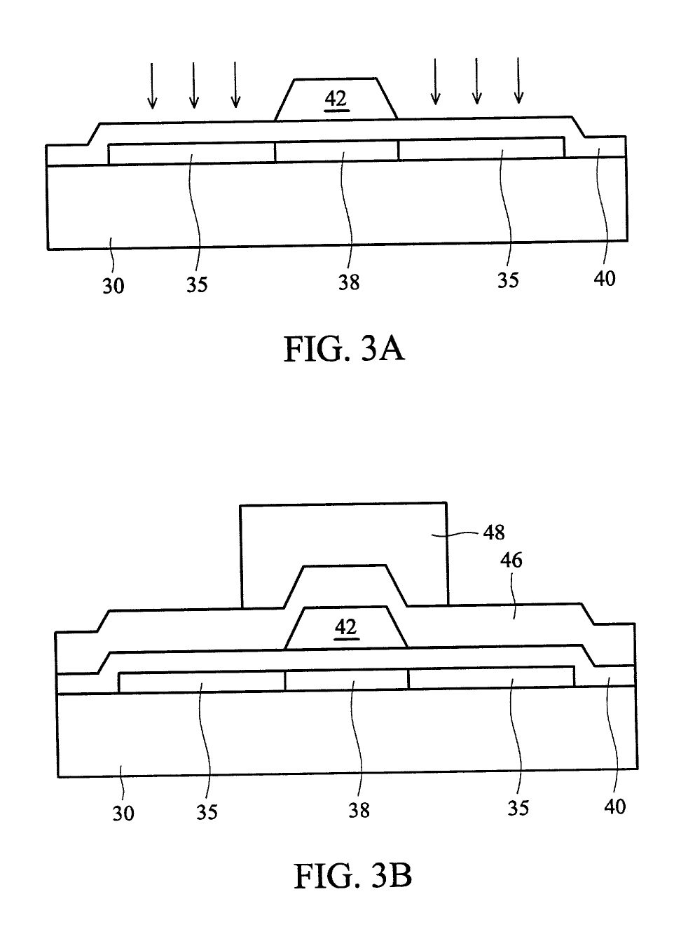

FIG. 2 is a cross-sectional diagram of a gate-overlapped LDD polysilicon TFT according to the present invention. The gate-overlapped LDD polysilicon TFT has a glass substrate 30 and a polysilicon layer formed on the substrate 30. In an example of forming an NMOS TFT, the polysilicon layer has a channel region 38, an LDD structure 36 (N diffusion region) surrounding the channel region 38, and a source/drain region 34 (N⁺ diffusion region) surrounding the LDD structure 36. In addition, a gate insulating layer 40 formed on the polysilicon layer, a first gate layer 42 patterned on the gate insulating layer 40 and positioned over the channel region 38, and a second gate layer 46 patterned on the first gate layer 42. The second gate layer 46 extends to cover a predetermined area of the gate insulating layer 40 that is over the LDD structure 36. In the preferred embodiment, the resistance of conductive materials used for the first gate layer 42 is smaller than the resistance of conductive materials than the second gate layer 46. Since the second gate layer 46 has larger resistance, a smaller couple capacitor is formed on the overlapped area. Additionally, the second gate layer 46 is used to protect the first gate layer 42 so as to increase the selectivity and reliability of the gate electrode.

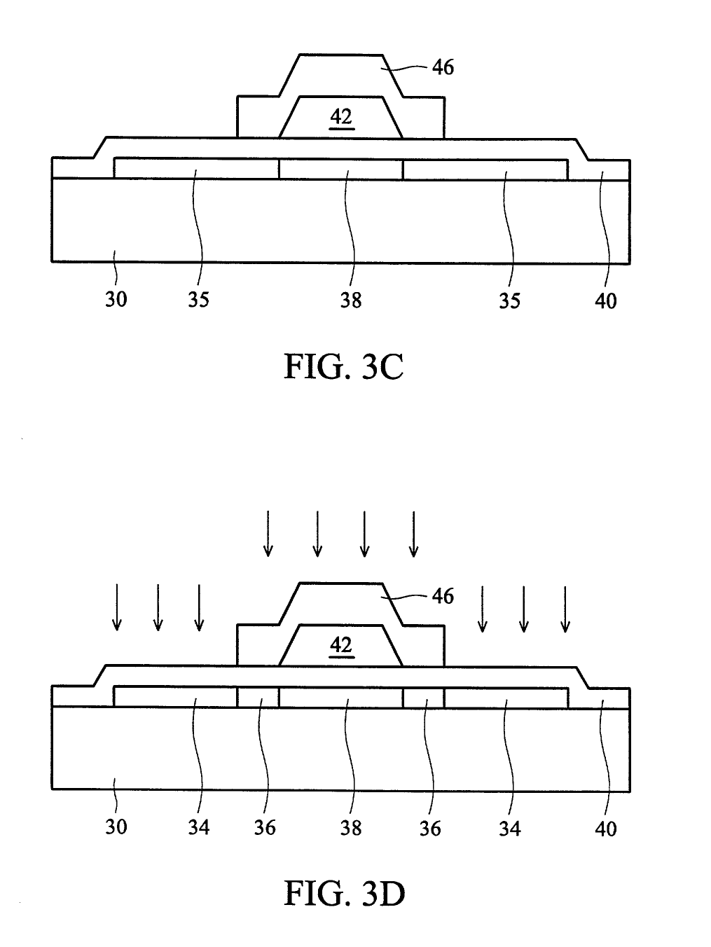

FIGS. 3A to 3D are cross-sectional diagrams showing a method of forming the gate-overlapped LDD polysilicon TFT shown in FIG. 2. As shown in FIG. 3A, the polysilicon layer is formed on a predetermined area of the substrate 30, and then the gate insulating layer 40 and the first gate layer 42 are sequentially deposited on the polysilicon layer. The first gate layer 42 is of conductive metal or alloy, such as Cr, MoW, Al, or Ta. Then, using photolithography and etching, the first gate 42 is patterned on the gate insulating layer 40. Next, using a first ion implantation process with the gate layer 42 as a mask, a N- diffusion region 35 is formed on the polysilicon layer surrounding the gate layer 42. Thus, the undoped region of the polysilicon layer serves as the channel region 38.

Next, as shown in FIG. 3B, the second gate layer 46 is deposited on the entire surface of the substrate 30 so as to cover the first gate layer 42 and the gate insulating layer 40. The second gate layer 46 may be polysilicon, amorphous silicon or conductive metal. Then, a patterned photoresist layer 48 is formed on the second gate layer 46 to cover part of the N⁻ diffusion region 35. Next, as shown in FIG. 3C, using etching with the patterned photoresist layer 48 as a mask, the second gate layer 46 is patterned for defining the position of the LDD structure 36 in the subsequent ion implantation process. The patterned photoresist layer 48 is stripped.

Then, as shown in FIG. 3D, using a second ion implantation process with the second gate layer 46 as a mask, an N⁺ diffusion region 34 is formed on the N- diffusion region 35 that is not covered by the second gate layer 46. Thus, the N⁺ diffusion region 34 serves as the source/drain region 34, and the remaining part of the N diffusion region 35 serves as the LDD structure 36. It is noted that if polysilicon or amorphous silicon is used to form the second gate layer 46, the second ion implantation process also can turn the second gate layer 46 into conductive materials.

Compared with the gate-overlapped LDD polysilicon TFT in the prior art, the present invention employs the patterned photoresist layer 48 to define the second gate layer 46 and then uses the second gate layer 46 to define the source/drain region 34 and the LDD structure 36 so as to assure that the second gate layer 46 covers over the LDD structure 36. Also, the second gate layer 46 can protect the first gate 42 to increase the reliability. Furthermore, the method of forming the gate-overlapped LDD polysilicon TFT is simplified.

It is to be understood that the present invention is not limited to the embodiments described above, but encompasses any and all embodiments within the scope of the following claims.

What is claimed is:

1. A gate-overlapped lightly doped drain (LDD) polysilicon thin film transistor (TFT), comprising:
a transparent insulating substrate;
a polysilicon layer formed on the substrate and having a channel region, an LDD structure surrounding the channel region, and a source/drain region surrounding the LDD structure;
a gate insulating layer formed on the polysilicon layer;
a first gate layer patterned on the gate insulating layer and positioned over the channel region; and
a second gate layer patterned on the first gate layer and extending to cover a predetermined area of the gate insulating layer that covers the LDD structure.

2. The gate-overlapped LDD polysilicon TFT according to claim 1, wherein the transparent insulating substrate is glass.

3. The gate-overlapped LDD polysilicon TFT according to claim 1, wherein the doped concentration of the LDD structure is smaller than the doped concentration of the source/drain region.

4. The gate-overlapped LDD polysilicon TFT according to claim 1, wherein the first gate layer is of conductive metal.

5. The gate-overlapped LDD polysilicon TFT according to claim 1, wherein the first gate layer is doped polysilicon, amorphous silicon or metal.

6. A method of forming a gate-overlapped LDD polysilicon TFT, comprising steps of:
providing a transparent insulating substrate which has a polysilicon layer, a gate insulating layer formed on the polysilicon layer, and a first gate layer patterned on the gate insulating layer;
performing a first ion implantation process to form a lightly doped region on the polysilicon layer surrounding the first gate layer;
forming a second gate layer on the first gate layer, wherein the second gate layer extends to cover a predetermined area of the gate insulating layer that is over part of the lightly doped region; and
performing a second ion implantation process to form a heavily doped region on the lightly doped region that surrounds the second gate layer.

7. The method according to claim 6, wherein the first gate layer is of conductive metal.

8. The method according to claim 6, wherein the polysilicon layer covered by the first gate layer serves as a channel region.

9. The method according to claim 6, wherein the heavily doped region serves as a source/drain region.

10. The method according to claim 6, wherein the lightly doped region serves as an LDD structure.
